(19) United States
(12) Patent Application Publication
(10) Pub. No.: US 2026/0130253 A1
(43) Pub. Date: May 7, 2026

(54) ELECTRONIC DEVICE

(71) Applicant: Japan Display Inc., Tokyo (JP)

(72) Inventors: Masanobu IKEDA, Tokyo (JP); Yoshitaka OZEKI, Tokyo (JP)

(73) Assignee: Japan Display Inc., Tokyo (JP)

(21) Appl. No.: 19/435,837

(22) Filed: Dec. 30, 2025

Related U.S. Application Data
(63) Continuation of application No. PCT/JP2024/016585, filed on Apr. 26, 2024.

(30) Foreign Application Priority Data
Jul. 5, 2023 (JP) 2023-110635

(51) Int. Cl. H10W 70/685; H10W 44/20; H10W 70/60; H10W 70/63; H10W 70/692; H10W 90/00; H10W 90/10; H10W 90/22

(52) U.S. Cl. CPC H10W 70/686; H10W 44/243; H10W 70/611; H10W 70/635; H10W 70/687; H10W 90/22; H10W 70/692; H10W 90/10; H10W 90/724

(57) ABSTRACT

An electronic device including a first aluminum nitride film configured to cover a first surface of the first glass substrate, a second aluminum nitride film configured to cover a second surface of the first glass substrate, wiring layers disposed on the first aluminum nitride film, a plurality of first terminals disposed on the wiring layers, a first electronic component mounted on the plurality of first terminals, a plurality of second terminals disposed on the second aluminum nitride film, a second electronic component mounted on the plurality of second terminals, and a first through-hole wiring penetrating the first aluminum nitride film, the second aluminum nitride film, and the first glass substrate are included. A first reference potential terminal among the plurality of first terminals and a second reference potential terminal among the plurality of second terminals are electrically connected to each other via the first through-hole wiring.

### CROSS-REFERENCES TO RELATED APPLICATIONS

The present application is a continuation of International Application No. PCT/JP2024/016585 filed on Apr. 26, 2024 and claims priority to Japanese Patent Application No. 2023-110635 filed on Jul. 5, 2023, the disclosure of each is incorporated herein by reference.

### BACKGROUND

The present disclosure relates to an electronic device.

Japanese Patent Application Laid-open Publication No. 05-243416 discloses a semiconductor package using an aluminum-nitride multilayer substrate as a wiring substrate on which a semiconductor element is mounted.

In addition, Japanese Patent Application Laid-open Publication No. 09-050936 discloses a built-in thin-film-capacitor module in which a thin-film capacitor is mounted on an aluminum-nitride substrate.

### SUMMARY

There is a technique of building a system in a package by mounting a plurality of electronic components having different functions from one another on a single package substrate. In addition, there is a technique in which a semiconductor wafer is used as a package substrate on which a plurality of electronic components are mounted, and in which multilayer wiring layers provided in the package substrate are formed by a wafer process. An electronic component manufactured by this technique is called an Fan-Out Wafer Level Package (FOWLP). The inventors of the present application are studying a technique of using a glass substrate as a package substrate on which a plurality of electronic components are mounted.

The object of the present disclosure is to provide a technique for improving the performance of an electronic device having a glass substrate.

According to one embodiment, an electronic device includes a first glass substrate having a first surface and a second surface opposite to the first surface, a first aluminum nitride film covering the first surface of the first glass substrate, a second aluminum nitride film covering the second surface of the first glass substrate, one or more wiring layers disposed on the first aluminum nitride film, a plurality of first terminals disposed on the one or more wiring layers, a first electronic component mounted on the plurality of first terminals, a plurality of second terminals disposed on the second aluminum nitride film, a second electronic component mounted on the plurality of second terminals, and a first through-hole wiring embedded in a through-hole that penetrates the first aluminum nitride film, the second aluminum nitride film, and the first glass substrate. The plurality of first terminals includes a first reference potential terminal capable of supplying a reference potential to the first electronic component. The plurality of second terminals includes a second reference potential terminal capable of supplying the reference potential to the second electronic component. Each of the first reference potential terminal and the second reference potential terminal is electrically connected via the first through-hole wiring.

### BRIEF DESCRIPTION OF THE DRAWINGS

FIG. 1 is a cross-sectional view illustrating a configuration example of an electronic device according to one embodiment.

FIG. 2 is an enlarged cross-sectional view illustrating a part of the electronic device illustrated in FIG. 1.

FIG. 3 is an enlarged cross-sectional view illustrating a portion A of FIG. 2.

FIG. 4 is an enlarged cross-sectional view illustrating a modification example with respect to FIG. 2.

FIG. 5 is an enlarged cross-sectional view illustrating a portion B of FIG. 4.

FIG. 6 is an enlarged cross-sectional view illustrating another modification example with respect to FIG. 2.

FIG. 7 is an enlarged cross-sectional view illustrating another modification example with respect to FIG. 2.

FIG. 8 is an enlarged cross-sectional view illustrating each of a portion C of FIG. 2 and a portion D of FIG. 7.

FIG. 9 is an enlarged cross-sectional view illustrating a modification example with respect to FIG. 7.

FIG. 10 is an enlarged cross-sectional view illustrating a portion E of FIG. 9.

FIG. 11 is an enlarged cross-sectional view illustrating another modification example with respect to FIG. 2.

FIG. 12 is an enlarged cross-sectional view illustrating a portion F of FIG. 11.

FIG. 13 is an enlarged cross-sectional view illustrating another modification example with respect to FIG. 2.

FIG. 14 is an enlarged cross-sectional view illustrating a portion G of FIG. 13.

FIG. 15 is an enlarged cross-sectional view illustrating another modification example with respect to FIG. 2.

FIG. 16 is an enlarged cross-sectional view illustrating another modification example with respect to FIG. 2.

### DETAILED DESCRIPTION

The embodiments of the present disclosure will be described below with reference to the drawings. It should be noted that the disclosure is merely an example, and any appropriate modifications that a person skilled in the art can easily conceive while maintaining the gist of the disclosure are naturally included within the scope of the present disclosure. In addition, the drawings may schematically illustrate widths, thicknesses, shapes, and the like of respective portions for the purpose of making the description clearer, as compared with actual modes, but these are merely examples and do not limit the interpretation of the present disclosure. Further, in the present specification and the drawings, elements similar to those previously described with respect to earlier drawings may be assigned the same or related reference numerals, and detailed description thereof may be omitted as appropriate.

In the embodiments below, a Fan Out Panel Level Package (FOPLP) will be described as an example of an electronic device including a glass substrate on which a plurality of electronic components are mounted. The FOPLP is an electronic device that can be manufactured more efficiently than an FOWLP by using a rectangular glass substrate having a larger area than a semiconductor wafer as a package substrate.

In the present application, the expression “member A is made of B” may be used when describing a material constituting a specific member. This expression means that, among the materials constituting member A, the material contained in the largest amount on a weight basis is B. Therefore, member A may be constituted purely of B without impurities, or may contain materials other than B as impurities.

### <Electronic Device>

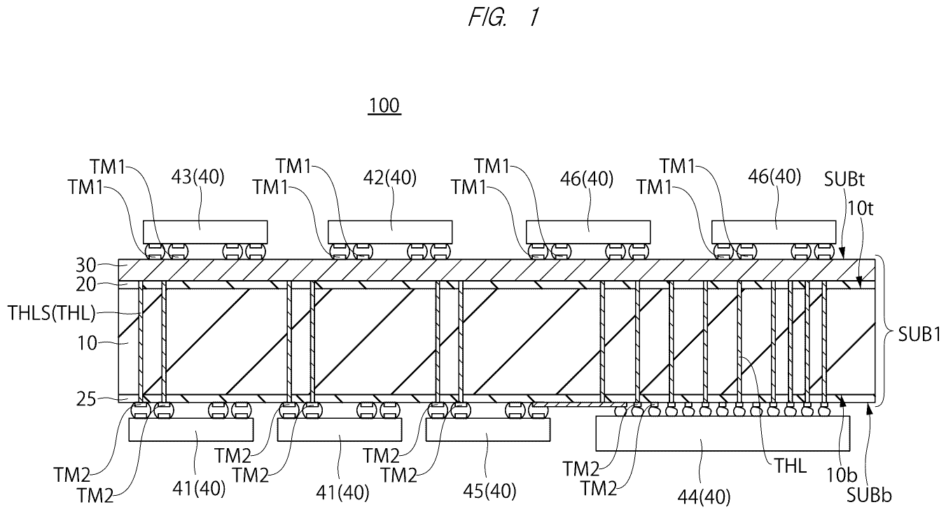

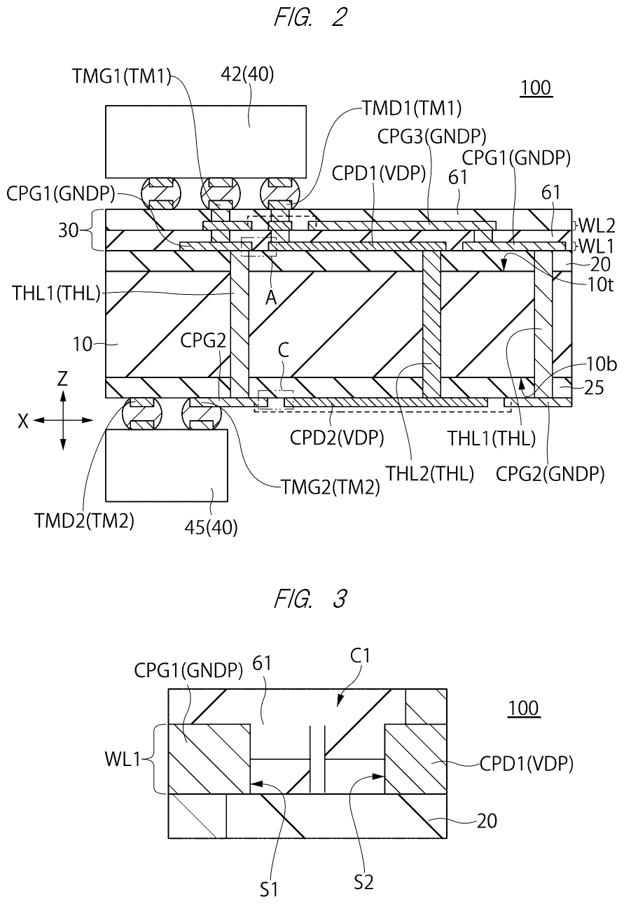

First, a configuration example of an electronic device according to one aspect of the present embodiment will be described. FIG. 1 is a cross-sectional view illustrating a configuration example of an electronic device according to one embodiment. FIG. 2 is an enlarged cross-sectional view illustrating a part of the electronic device illustrated in FIG. 1. FIG. 3 is an enlarged cross-sectional view illustrating a portion A of FIG. 2. In FIG. 2, among a plurality of conductor patterns, conductor patterns that are electrically connected to each other are schematically illustrated using dotted lines to indicate their electrical connection relationships. In the drawings illustrating modification examples with respect to FIG. 2, as described below, the same manner of illustration is employed.

An electronic device 100 illustrated in FIG. 1 includes a substrate SUB1 and a plurality of electronic components 40 mounted on the substrate SUB1. The substrate SUB1 has a surface SUBt and a surface SUBb opposite to the surface SUBt. A plurality of electronic components 40 are mounted on each of the surface SUBt and the surface SUBb of the substrate SUB1.

The variations of the plurality of electronic components 40 included in the electronic device 100, which is an FOPLP, are wide-ranging.

For example, the plurality of electronic components 40 may include sensor components. Examples of sensor components include, for example, a light sensor that detects light, a gas sensor that detects a specific gas, and a physical quantity sensor that measures physical quantities such as speed or acceleration. A physical quantity sensor is an electronic component 40 that incorporates, for example, a semiconductor chip manufactured using a technique such as Micro Electro Mechanical Systems (MEMS).

In addition, the plurality of electronic components 40 may include logic components including an arithmetic processing circuit configured to receive an electrical signal from an electronic component 40 such as a sensor component and to perform arithmetic processing on the received signal. For example, an electronic component 42 illustrated in FIG. 1 is a logic component. The logic component (the electronic component 42) generates a new control signal based on the result of the arithmetic processing and controls other electronic components 40 by transmitting the control signal to the other electronic components 40. The logic component (the electronic component 42) includes a high-frequency circuit for performing signal transmission and reception and arithmetic processing at high speed.

In addition, the plurality of electronic components 40 may include memory components that transmit and receive signals to and from the electronic component 42, which is a logic component, and store data. For example, an electronic component 43 illustrated in FIG. 1 is a memory component. The electronic component 42 and the electronic component 43 are electrically connected to each other via a wiring portion 30.

In addition, the plurality of electronic components 40 may include a power supply component (battery component) capable of supplying power to the plurality of electronic components 40. Further, when the plurality of electronic components 40 includes a power supply component, it is preferable that the plurality of electronic components 40 includes a power supply control component that controls power supply from the power supply component to the plurality of electronic components 40. For example, an electronic component 44 illustrated in FIG. 1 is a power supply component. The electronic component 45 is a power supply control component. Although power may be supplied to the plurality of electronic components 40 from an external power source (not illustrated), it is preferable that the electronic device 100 include the power supply components because the power supply path can be shortened.

In addition, the plurality of electronic components 40 may include a communication component for performing wireless communication with an external device. For example, electronic components 46 illustrated in FIG. 1 are communication components. Examples of communication components include an electromagnetic-wave communication component that transmits and receives electromagnetic-wave signals using an antenna or a coil, and an optical communication component that transmits and receives optical signals using a light-emitting element or a light-receiving element.

In the example illustrated in FIG. 1, each of the electronic components 41, 43, 45, and 46 operates based on a control signal generated by the electronic component 42, which is a logic component.

The electronic device 100 can be connected to an external device via an external terminal (not illustrated). As the external terminal, for example, a connector (not illustrated) can be used. In this case, the electronic device 100 is electrically connected to the external device via a flexible wiring board (not illustrated) connected to the connector. As a modification example of the external terminal, a terminal such as a solder ball may also be used. In this case, the substrate SUB1 is provided with terminals for connecting the solder balls, and the electronic device 100 is mounted on a mounting substrate (not illustrated) via the solder balls.

The substrate SUB1 includes a glass substrate 10, an aluminum nitride film 20 that covers a surface 10t of the glass substrate 10, and an aluminum nitride film 25 that covers a surface 10b of the glass substrate 10. The substrate SUB1 further includes a wiring portion 30 disposed on the aluminum nitride film 20. The wiring portion 30 is a transmission path including one or more wiring layers. In the case of the present embodiment, as illustrated in FIG. 2, the wiring portion 30 is a transmission path having a two-layer structure including a wiring layer WL1 and a wiring layer WL2 (or a three-layer structure if a layer in which a plurality of terminals TM1 is formed is included).

A plurality of terminals TM1 is disposed on the wiring portion 30. A plurality of terminals TM2 is disposed on the aluminum nitride film 25. Among the plurality of electronic components 40 illustrated in FIG. 1, each of the electronic component 42, the electronic component 43, and the electronic component 46 is mounted on the terminal TM1. Among the plurality of electronic components 40, each of the electronic component 41, the electronic component 44, and the electronic component 45 is mounted on the terminal TM2.

In addition, the electronic device 100 includes a plurality of through-hole wirings THL embedded in through-holes penetrating the aluminum nitride film 20, the aluminum nitride film 25, and the glass substrate 10.

As illustrated in FIG. 2, the glass substrate 10 has a surface 10t and a surface 10b opposite to the surface 10t. The glass constituting the glass substrate 10 is, for example, glass called so-called alkali-free glass and, except for impurities mixed therein due to carry-over or the like, substantially contains no alkali metal. The glass substrate 10 contains, for example, 55 mol % or more of silicon oxide (SiO₂), 5 mol % or more of aluminum oxide (Al₂O₃), and one or more alkaline-earth metal oxides.

In addition, characteristics possessed by the glass substrate 10 used in the present embodiment are, for example, as follows. The thickness Ti (a distance from the surface 10t to the surface 10b) is approximately 0.3 to 0.8 mm. The density is 2.50 to 2.60 [g/cm³]. The Young's modulus is 70 to 85 [GPa]. The thermal expansion coefficient is 3.5 to 3.8×10⁻⁶ [1/K]. The strain point is 670 to 750 degrees Celsius. It should be noted that the above characteristics are merely examples, and various modification examples exist in the characteristics of the glass substrate 10.

When an FOPLP using the glass substrate 10 is employed as the package substrate, the substrate size during the manufacturing process can be increased, for example, as compared with an FOWLP using a semiconductor wafer such as a silicon substrate. In this case, since a large number of electronic devices 100 can be manufactured collectively, manufacturing efficiency is improved.

### <Warp Deformation of Substrate>

When the substrate size is increased during manufacturing, a problem associated with the increased size arise. For example, as illustrated in FIG. 1, in a structure in which the wiring portion 30 is provided on one side of the glass substrate 10 (the surface 10t side in FIG. 1) and the wiring portion 30 is not provided on the other side (the surface 10b side in FIG. 1), warp deformation may occur in the glass substrate 10 due to a difference in the linear expansion coefficients between the wiring portion 30 and the glass substrate 10. Even when the wiring portion 30 is provided on both surfaces of the glass substrate 10, similar warp deformation may occur in the glass substrate 10 if the number of stacked layers or the metal content of the wiring portion 30 differs.

When warp deformation occurs in the glass substrate 10 during the manufacturing process of the electronic device 100, a problem arises in that the accuracy of pattern formation of the wiring portion 30 decreases because exposure becomes difficult depending on the degree of deformation.

In the electronic device 100 of the present embodiment, the glass substrate 10 is interposed between the aluminum nitride film 20 and the aluminum nitride film 25. That is, the electronic device 100 includes the aluminum nitride film 20 that covers the surface 10t of the glass substrate 10 and the aluminum nitride film 25 that covers the surface 10b of the glass substrate 10. In the example illustrated in FIGS. 1 and 2, the aluminum nitride film 20 is in contact with the surface 10t of the glass substrate 10. The aluminum nitride film 25 is also in contact with the surface 10b of the glass substrate 10.

The Young's modulus of aluminum nitride is 300 [GPa] or more. Therefore, in the case of the substrate SUB1 of the present embodiment, even when stress occurs during the manufacturing process of the wiring portion 30 due to a difference in the linear expansion coefficients between the wiring portion 30 and the glass substrate 10 (and the aluminum nitride films 20 and 25), the degree of warp deformation can be suppressed.

When the substrate SUB1 of the present embodiment is compared with a so-called aluminum nitride substrate in which the entire substrate is formed of aluminum nitride, the following can be said. That is, the substrate SUB1 in which the aluminum nitride film 20 is formed on the surface 10t of the glass substrate 10 and the aluminum nitride film 25 is formed on the surface 10b is preferable in that the manufacturing cost can be reduced as compared with the aluminum nitride substrate.

### <Heat Dissipation Characteristics of Substrate>

In addition, in the case of an FOPLP that uses the glass substrate 10 as the package substrate, there is room for improvement in the following respects as compared with an FOWLP that uses a semiconductor wafer. For example, the thermal conductivity of the glass substrate 10 is approximately 1.6 [W/m·K], which is 1% of the thermal conductivity of a silicon wafer, which is approximately 160 [W/m·K].

In the FOPLP, a plurality of electronic components 40 is mounted on the substrate SUB1. From the viewpoint of allowing these electronic components 40 to operate normally, it is preferable that the substrate SUB1 have high heat dissipation characteristics. This is because heat generated by the electronic components 40 during use can be released efficiently to the outside, thereby stabilizing the operation of the electronic components 40.

In the case of the present embodiment, as described above, the glass substrate 10 is interposed between the aluminum nitride film 20 and the aluminum nitride film 25. That is, the electronic device 100 includes the aluminum nitride film 20 that covers the surface 10t of the glass substrate 10 and the aluminum nitride film 25 that covers the surface 10b of the glass substrate 10. The thermal conductivity of aluminum nitride is approximately 80 to 150 [W/m·K]. This is approximately 50 to 100 times higher than the thermal conductivity of the glass substrate 10.

Therefore, in the case of the substrate SUB1 of the present embodiment, the aluminum nitride film 20 and the aluminum nitride film 25 function as heat dissipation members that release the heat transferred from the electronic components 40 to the outside. As a result, the heat dissipation characteristics, which are a concern of the glass substrate 10, can be improved.

### <Countermeasures Against Power Supply Noise>

In an FOPLP such as the electronic device 100 in which a plurality of electronic components 40 is mounted, it is necessary to take measures against noise in the power supply potential supplied to the plurality of electronic components 40. For example, in a case where a logic component, such as the electronic component 42 having an arithmetic processing circuit, is included, the power demand may change instantaneously in accordance with the operating state of a high-frequency circuit such as the arithmetic processing circuit, and noise (induced voltage caused by a change in current) may occur in the power supply potential supply path.

As an electrical-circuit countermeasure against such power supply noise, there is a countermeasure of providing a capacitor so as to connect the power supply potential and the reference potential. This capacitor is called a decoupling capacitor. The decoupling capacitor has a function of absorbing a current change of a load (for example, an arithmetic processing circuit) by charging and discharging characteristics of the capacitor, thereby suppressing the occurrence of noise in a power supply potential supply path.

Further, the decoupling capacitor has a function of confining a high-frequency current generated in a power supply potential supply path of a load within a loop between the load and the decoupling capacitor, and suppressing the diffusion of the current to other power supply wirings.

In order for these functions of the decoupling capacitor to be exhibited effectively, it is preferable that the transmission distance between the decoupling capacitor and the load be short. For this reason, when a capacitor component is used as the decoupling capacitor, it is necessary to mount a large number of capacitor components near the electronic component 40.

When a large number of capacitor components are mounted in the vicinity of the electronic component 40, the effective mounting area of the electronic component 40 increases in consideration of the mounting space required for the capacitor components. From the viewpoint of downsizing the electronic device 100, it is preferable to reduce the mounting area of the electronic component 40.

Accordingly, the present inventors have examined a technique in which a conductor pattern constituting a reference potential supply path used as a decoupling capacitor in place of the above-described large number of capacitor components.

As illustrated in FIG. 2, the electronic device 100 includes a plurality of terminals TM1 disposed on the wiring layer WL1 and the wiring layer WL2, and a plurality of terminals TM2 disposed on the aluminum nitride film 25. The electronic device 100 also includes the electronic component 42 mounted on the plurality of terminals TM1 and the electronic component 45 mounted on the plurality of terminals TM2. The electronic device 100 further includes a through-hole wiring THL1 embedded in a through-hole that penetrates the aluminum nitride film 20, the aluminum nitride film 25, and the glass substrate 10.

The plurality of terminals TM1 include a reference potential terminal TMG1 that can supply a reference potential to the electronic component 42. The plurality of terminals TM1 also include a power supply potential terminal TMD1 that can supply a power supply potential to the electronic component 42. The plurality of terminals TM2 include a reference potential terminal TMG2 that can supply a reference potential to the electronic component 45. A power supply potential supply path VDP connected to the power supply potential terminal TMD1 and a reference potential supply path GNDP connected to the reference potential terminal TMG1 are disposed so as to be adjacent to each other in either the wiring layer WL1 or the wiring layer WL2. Each of the reference potential terminal TMG1 and the reference potential terminal TMG2 is electrically connected via the through-hole wiring THL1. The potential supplied to the reference potential supply path GNDP is, for example, a ground potential.

In the case of the present embodiment, the reference potential supply path GNDP disposed on the surface 10t and the reference potential supply path GNDP disposed on the surface 10b of the glass substrate 10 are electrically connected via the through-hole wiring THL1. In a portion where the power supply potential supply path VDP to the electronic component 42 and the reference potential supply path GNDP are adjacent to each other, a capacitor portion C1 (see FIG. 3) that functions as a decoupling capacitor is formed.

The potential at any location of the conductor pattern to which the reference potential is supplied can be stabilized. In the example illustrated in FIG. 2, the reference potential supply path GNDP disposed on the surface 10t and the reference potential supply path GNDP disposed on the surface 10b of the glass substrate 10 are electrically connected via the plurality of through-hole wirings THL1. Accordingly, the reference potential can be further stabilized.

As illustrated in FIG. 3, the one or more wiring layers (the wiring portion 30) include the wiring layer WL1 disposed on the aluminum nitride film 20. The wiring layer WL1 includes a reference potential pattern CPG1 connected to the through-hole wiring THL1 and a power supply potential pattern CPD1 electrically connected to the power supply potential terminal TMD1. In the wiring layer WL1, a side surface S1 of the reference potential pattern CPG1 and a side surface S2 of the power supply potential pattern CPD1 face each other. The capacitor portion C1 is formed between the side surface S1 and the side surface S2 that are disposed to face each other.

In the example illustrated in FIG. 2, a portion of the reference potential pattern CPG1 and a portion of the power supply potential pattern CPD1 face each other in a thickness direction (Z-direction) with an organic insulating film 61 interposed therebetween. However, the organic insulating film 61 is an insulating film having a low dielectric constant (for example, a relative dielectric constant of 3.8 or less) from the viewpoint of suppressing wiring delay. Examples of organic materials constituting the organic insulating film 61 include acrylic resin, polyimide resin, and benzocyclobutene.

More specifically, when the plurality of electronic components 40 mounted on the substrate SUB1 is electrically connected via the wiring portion 30, as illustrated in FIG. 1, it is necessary to suppress wiring delay corresponding to a time constant (CR), which is the product of a capacitance component (C) and a resistance component (R) occurring in the wiring that electrically connects the plurality of electronic components 40. By using copper as the wiring material of the wiring portion 30 and as the material of the through-hole wiring THL, the resistance component (R) of the wiring can be reduced. In addition, as illustrated in FIG. 2, by reducing the relative dielectric constant of the organic insulating film 61 that covers each of the wiring layer WL1 and the wiring layer WL2, the capacitance component (C) coupled to the wiring can be reduced.

In the case of the present embodiment, each of the plurality of conductor patterns constituting the wiring portion 30 is made of copper or a copper alloy. More specifically, each of the wiring layer WL1, the wiring layer WL2, and the plurality of terminals TM1 illustrated in FIG. 2 is made of copper or a copper alloy. Each of the plurality of through-hole wirings THL including the through-hole wiring THL1 (see FIG. 1) is also made of copper or a copper alloy. In this case, in the conductive path that passes through the wiring portion 30, the resistance component of the wiring can be reduced. Similarly, the plurality of terminals TM2 are made of copper or a copper alloy. When the terminals TM2 are formed directly on the aluminum nitride film 25, as illustrated in FIG. 2, the path length of a transmission path passing through the terminals TM2 is shorter than that of a transmission path passing through the wiring portion 30. Therefore, by using copper or a copper alloy, the effect of reducing the wiring delay by reducing the time constant (CR product) is particularly effective when applied to the transmission path that passes through the wiring portion 30.

In the case of the present embodiment, each of the reference potential pattern CPG1 and the power supply potential pattern CPD1 of the wiring layer WL1 is covered with the organic insulating film 61. The relative dielectric constant of the organic insulating film 61 is lower than the relative dielectric constant of the aluminum nitride film 20. Accordingly, the capacitance component coupled to the wiring formed in the wiring layer WL1 can be reduced.

On the other hand, the wiring layer WL1 is in contact with the aluminum nitride film 20. The relative dielectric constant of the aluminum nitride film 20 is higher than the relative dielectric constant of the glass substrate 10 (for example, 5.5), and is, for example, 8.5. Therefore, in the wiring layer WL1 formed so as to be in contact with the aluminum nitride film 20, the capacitor portion C1 formed between the side surface S1 and the side surface S2 that face each other can obtain a required capacitance as a decoupling capacitor due to the influence of the aluminum nitride film 20 having a high relative dielectric constant.

### Modification Example 1

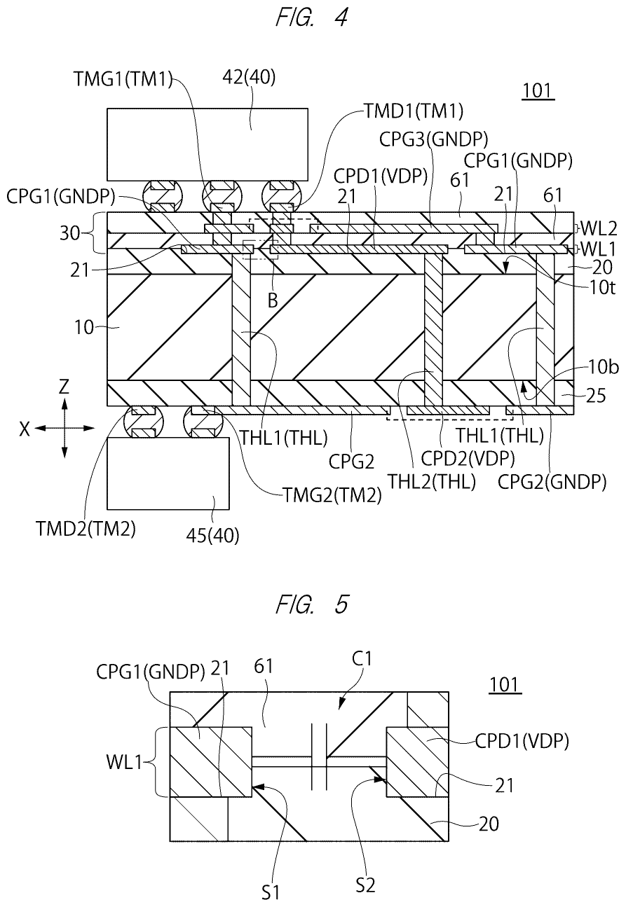

FIG. 4 is an enlarged cross-sectional view illustrating a modification example with respect to FIG. 2. FIG. 5 is an enlarged cross-sectional view illustrating a portion B of FIG. 4.

In an electronic device 101 illustrated in FIG. 4, the aluminum nitride film 20 has a plurality of recesses 21, and this is a point different from the electronic device 100 illustrated in FIG. 2. Each of the reference potential pattern CPG1 and the power supply potential pattern CPD1 is disposed such that at least a part thereof is located in one of the plurality of recesses 21 provided in the aluminum nitride film 20.

In addition, as illustrated in FIG. 5, a portion of the aluminum nitride film 20 is interposed between the side surface S1 of the reference potential pattern CPG1 and the side surface S2 of the power supply potential pattern CPD1. In the case of the electronic device 100 illustrated in FIG. 3, the aluminum nitride film 20 is not interposed between the side surface S1 of the reference potential pattern CPG1 and the side surface S2 of the power supply potential pattern CPD1, and the organic insulating film 61 is interposed. The electronic device 101 illustrated in FIGS. 4 and 5 is different from the electronic device 100 illustrated in FIGS. 2 and 3 in this respect.

In the case of the electronic device 101 according to the present modification example, the capacitor portion C1 includes the aluminum nitride film 20 having a higher relative dielectric constant than the organic insulating film 61. Accordingly, as compared with the electronic device 100 illustrated in FIG. 2, the capacitance of the capacitor portion C1 can be increased. When the capacitance of the capacitor portion C1 functioning as a decoupling capacitor increases, the margin of voltage variation that can be suppressed by the decoupling capacitor can be increased.

In the example illustrated in FIG. 5, a part of the side surface S1 is covered with the aluminum nitride film 20, and another part (the remaining part) of the side surface S1 is covered with the organic insulating film 61. A part of the side surface S2 is covered with the aluminum nitride film 20, and another part (the remaining part) of the side surface S2 is covered with the organic insulating film 61.

Although not illustrated, as a further modification example to the electronic device 101, the entirety of the side surface S1 and the side surface S2 illustrated in FIG. 5 may be covered with the aluminum nitride film 20. In other words, each of the conductor patterns constituting the wiring layer WL1 may be embedded in one of the plurality of recesses 21. In this case, the capacitance of the capacitor portion C1 can be further increased as compared with the electronic device 101.

However, when each of the conductor patterns constituting the wiring layer WL1 is embedded in one of the plurality of recesses 21, the parasitic capacitance between wirings in the wiring layer WL1 increases. As a result, there is a concern that wiring delay corresponding to a time constant (CR), which is the product of a capacitance component (C) and a resistance component (R) occurring in the wiring, increases.

Therefore, from the viewpoint of increasing the function of the capacitor portion C1 as a decoupling capacitor while suppressing wiring delay, it is preferable that the side surface S1 be covered with both the aluminum nitride film 20 and the organic insulating film 61, as in the electronic device 101 illustrated in FIG. 5. It is also preferable that the side surface S2 be covered with both the aluminum nitride film 20 and the organic insulating film 61.

The electronic device 101 illustrated in FIGS. 4 and 5 is the same as the electronic device 100 illustrated in FIGS. 2 and 3 except for the differences described above. Accordingly, redundant description is omitted.

### Modification Example 2

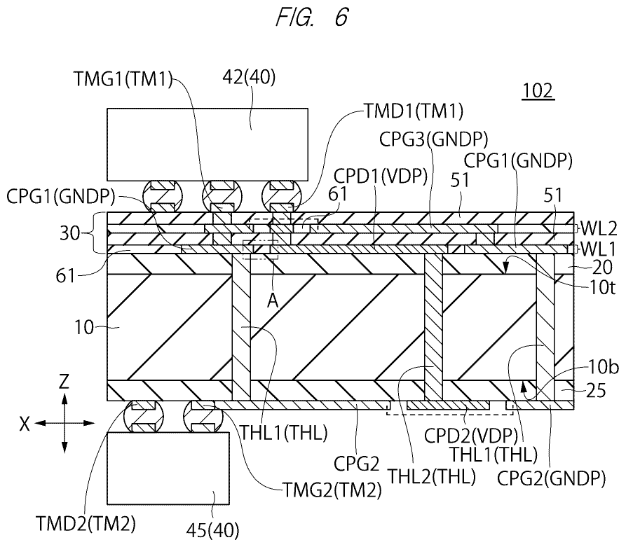

FIG. 6 is an enlarged cross-sectional view illustrating another modification example with respect to FIG. 2.

In the case of an electronic device 102 illustrated in FIG. 6, the wiring portion 30 includes an inorganic insulating layer 51 in addition to the organic insulating film 61, and this is a point different from the electronic device 100 illustrated in FIG. 2. In the electronic device 102, the inorganic insulating layer 51 is interposed between the layer in which the plurality of terminals TM1 are disposed and the organic insulating film 61.

In the example illustrated in FIG. 6, the inorganic insulating layer 51 is disposed between the wiring layer WL1 and the wiring layer WL2, and is disposed between the wiring layer WL2 and the layer in which the plurality of terminals TM1, respectively. Between the plurality of conductor patterns (for example, the reference potential pattern CPG1 and the power supply potential pattern CPD1) formed in the wiring layer WL1, the organic insulating film 61 is disposed. Between the plurality of conductor patterns (for example, the reference potential pattern CPG3) formed in the wiring layer WL2, the organic insulating film 61 is disposed.

In the case of the present modification example, as compared with the electronic device 100 illustrated in FIG. 2, the mechanical strength of the wiring portion 30 can be improved. For example, when mounting the electronic component 40, the electronic component 40 is pressed against the terminals TM1 of the substrate SUB1 (see FIG. 3) in order to electrically connect the electronic component 40 and the plurality of terminals TM1. From the viewpoint of suppressing damage to the wiring portion 30 due to mechanical external force applied at this point, it is preferable that part of the plurality of insulating layers of the wiring portion 30 be an inorganic insulating layer.

Examples of inorganic materials constituting the inorganic insulating layer 51 include silicon oxide (SiO₂) and fluorine-added silicon oxide (SiOF).

FIG. 6 illustrates a modification example with respect to FIG. 2. The structure of the electronic device 102 according to the modification example may be combined with the structure of the electronic device 101 illustrated in FIGS. 4 and 5, although the illustration is omitted.

The electronic device 102 illustrated in FIG. 6 is the same as the electronic device 100 illustrated in FIGS. 2 and 3 except for the differences described above. Accordingly, redundant description is omitted.

### Modification Example 3

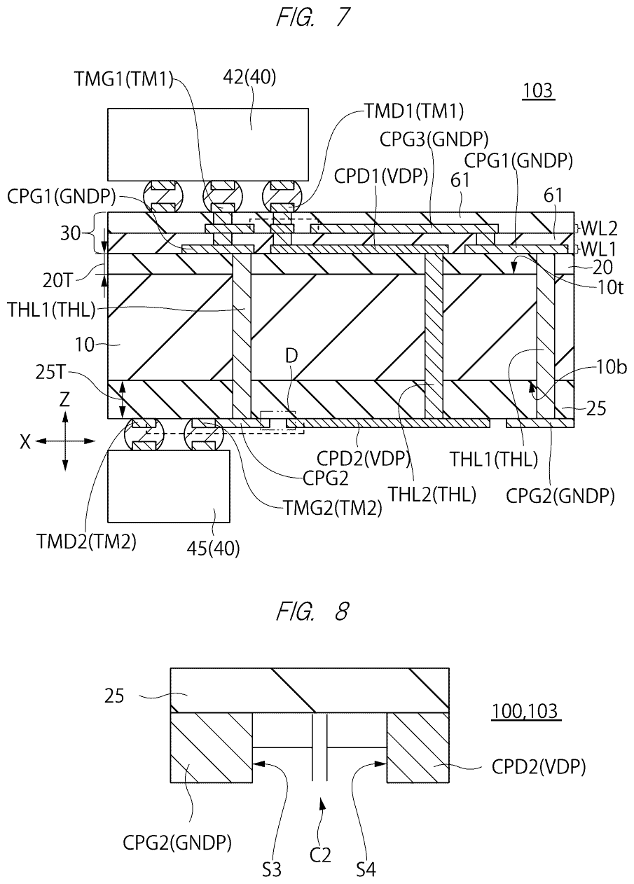

FIG. 7 is an enlarged cross-sectional view illustrating another modification example with respect to FIG. 2. FIG. 8 is an enlarged cross-sectional view illustrating each of a portion C of FIG. 2 and a portion D of FIG. 7. The electronic device 103 illustrated in FIG. 7 has the same structure as the electronic device 100 illustrated in FIG. 2 except for the thickness 25T of the aluminum nitride film 25. Accordingly, FIG. 8 corresponds to the portion C illustrated in FIG. 2 and the portion D illustrated in FIG. 7.

In the case of the electronic device 103 illustrated in FIG. 7, the plurality of terminals TM2 is in contact with the aluminum nitride film 25. In other words, in the case of the electronic device 103, a wiring portion similar to the wiring portion 30 is not interposed between the plurality of terminals TM2 and the aluminum nitride film 25.

When the wiring portion 30 is formed on one surface of the glass substrate 10 (the surface 10t illustrated in FIG. 1) and is not formed on the other surface (the surface 10b illustrated in FIG. 1), warp deformation is more likely to occur as compared with a case where wiring portions are equally formed on both surfaces.

Accordingly, in the case of the modification example, as illustrated in FIG. 7, the thickness 25T of the aluminum nitride film 25 is greater than the thickness 20T of the aluminum nitride film 20. In the electronic device 100 illustrated in FIG. 2, the thickness of the aluminum nitride film 25 is equal to the thickness of the aluminum nitride film 20. In this respect, the electronic device 103 illustrated in FIG. 7 is different from the electronic device 100 illustrated in FIG. 2.

Since, in the electronic device 103, the thickness 25T of the aluminum nitride film 25 is greater than the thickness 20T of the aluminum nitride film 20, warp deformation can be suppressed as compared with the electronic device 100 illustrated in FIG. 2.

As illustrated in FIGS. 2 and 7, a plurality of conductor patterns including the plurality of terminals TM2 are disposed on the aluminum nitride film 25. Each of the plurality of conductor patterns is in contact with the aluminum nitride film 25. The plurality of conductor patterns includes power supply potential terminals TMD2, reference potential pattern CPG2, and a power supply potential pattern CPD2.

The power supply potential terminals TMD2 included in the plurality of terminals TM2 are terminals capable of supplying a power supply potential to the electronic component 45. The reference potential pattern CPG2 is connected to the through-hole wiring THL1. The power supply potential pattern CPD2 is connected to the power supply potential terminals TMD2.

In addition, as illustrated in FIG. 8, in the layer in which the terminal TM2 is formed, the side surface S3 of the reference potential pattern CPG2 and the side surface S4 of the power supply potential pattern CPD2 face each other. Therefore, in a portion where the power supply potential supply path VDP to the electronic component 45 and the reference potential supply path GNDP are adjacent to each other, as illustrated in FIG. 8, a capacitor portion C2 that functions as a decoupling capacitor is formed. The capacitor portion C2 is formed between the side surface S3 and the side surface S4 that are disposed to face each other. Accordingly, the influence of noise in the power supply potential supply path connected to the power supply potential terminal TMD2 can be reduced.

In the example illustrated in FIG. 7, the power supply potential supplied to the electronic component 42 and the power supply potential supplied to the electronic component 45 are the same potential. Accordingly, the power supply potential terminal TMD2 and the power supply potential terminal TMD1 are electrically connected via the power supply potential supply path VDP. However, as a modification example, the power supply potential (first power supply potential) supplied to the electronic component 42 and the power supply potential (second power supply potential) supplied to the electronic component 45 may be different from each other. In this case, the power supply potential terminal TMD2 and the power supply potential terminal TMD1 are electrically separated. The first power supply potential is supplied to the electronic component 42 via a first power supply potential supply path, and the second power supply potential is supplied to the electronic component 45 via a second power supply potential supply path that is electrically separated from the first power supply potential supply path.

FIG. 7 illustrates a modification example with respect to FIG. 2. Although not illustrated, the structure of the electronic device 103 according to the modification example may be combined with either one or both of the structure of the electronic device 101 illustrated in FIGS. 4 and 5 and the structure of the electronic device 102 illustrated in FIG. 6.

The electronic device 103 illustrated in FIGS. 7 and 8 is the same as the electronic device 100 illustrated in FIGS. 2 and 3 except for the differences described above. Accordingly, redundant description is omitted.

### Modification Example 4

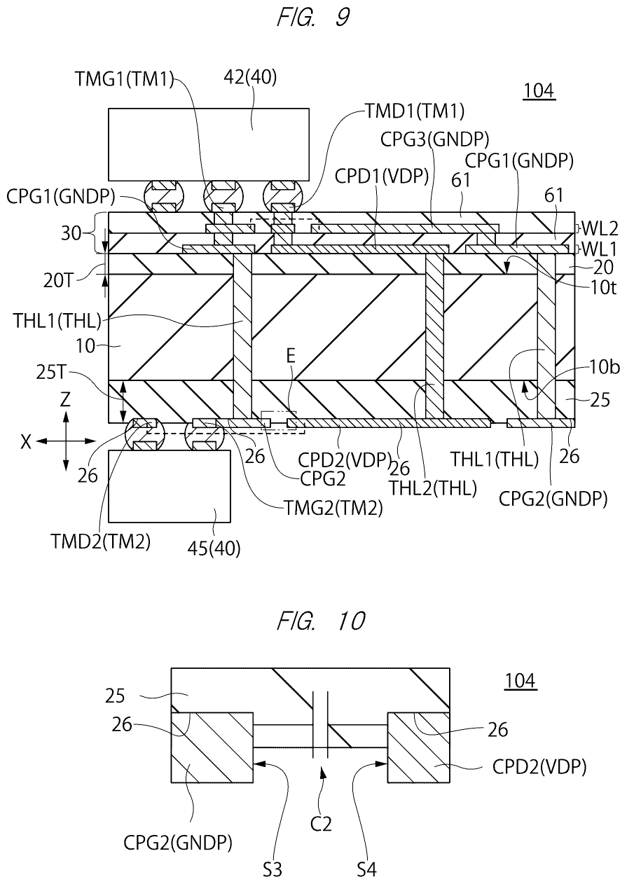

FIG. 9 is an enlarged cross-sectional view illustrating a modification example with respect to FIG. 7. FIG. 10 is an enlarged cross-sectional view illustrating a portion E of FIG. 9.

In the case of an electronic device 104 illustrated in FIGS. 9 and 10, the aluminum nitride film 25 has a plurality of recesses 26, and this is a point different from the electronic device 100 illustrated in FIG. 7. Each of the reference potential pattern CPG2 and the power supply potential pattern CPD2 is disposed such that at least a part thereof is located in one of the plurality of recesses 26 provided in the aluminum nitride film 25.

In addition, as illustrated in FIG. 10, a portion of the aluminum nitride film 25 is interposed between the side surface S3 of the reference potential pattern CPG2 and the side surface S4 of the power supply potential pattern CPD2. In the case of the electronic device 103 illustrated in FIG. 8, the aluminum nitride film 25 is not interposed between the side surface S3 of the reference potential pattern CPG2 and the side surface S4 of the power supply potential pattern CPD2. The electronic device 104 illustrated in FIGS. 9 and 10 is different from the electronic device 103 illustrated in FIGS. 7 and 8 in this respect.

In the case of the electronic device 104 according to the modification example, the capacitor portion C2 includes the aluminum nitride film 25 having a higher relative dielectric constant than the organic insulating film 61. Accordingly, as compared with the electronic device 100 illustrated in FIG. 2 and the electronic device 103 illustrated in FIG. 7, the capacitance of the capacitor portion C2 can be increased. When the capacitance of the capacitor portion C2 functioning as a decoupling capacitor increases, the margin of voltage variation that can be suppressed by the decoupling capacitor can be increased.

In the example illustrated in FIG. 10, a part of the side surface S3 is covered with the aluminum nitride film 25, and another part (the remaining part) of the side surface S3 is exposed to the outside. A part of the side surface S4 is covered with the aluminum nitride film 25, and another part (the remaining part) of the side surface S4 is exposed to the outside.

Similarly to the case of the electronic device 101 described with reference to FIGS. 4 and 5, as a further modification example of the electronic device 104 illustrated in FIGS. 9 and 10, the entirety of the side surface S3 and the side surface S4 illustrated in FIG. 10 may be covered with the aluminum nitride film 25. In this case, the capacitance of the capacitor portion C2 can be further increased as compared with the electronic device 104.

However, when each of the plurality of terminals TM2 is embedded in any of the plurality of recesses 26, the parasitic capacitance of the wiring path connected to the terminal TM2 increases. As a result, there is a concern that wiring delay corresponding to a time constant (CR), which is the product of a capacitance component (C) and a resistance component (R) occurring in the wiring, increases.

Therefore, from the viewpoint of increasing the function of the capacitor portion C2 as a decoupling capacitor while suppressing wiring delay, it is preferable that only a part of the side surface S3 be covered with the aluminum nitride film 25, as in the electronic device 104 illustrated in FIG. 10. It is also preferable that only a part of the side surface S4 be covered with the aluminum nitride film 25.

The electronic device 104 illustrated in FIGS. 9 and 10 is illustrated as a modification example with respect to the electronic device 103 illustrated in FIG. 7. Although not illustrated, the structure of the electronic device 104 according to the modification example may be combined with one or more of the structure of the electronic device 100 illustrated in FIGS. 2 and 3, the structure of the electronic device 101 illustrated in FIGS. 4 and 5, and the structure of the electronic device 102 illustrated in FIG. 6.

For example, as a modification example of the electronic device 104 illustrated in FIG. 9, the thickness of the aluminum nitride film 20 may be equal to the thickness of the aluminum nitride film 25, as in the electronic device 100 illustrated in FIG. 2.

The electronic device 104 illustrated in FIGS. 9 and 10 is the same as the electronic device 103 illustrated in FIGS. 7 and 8 except for the differences described above. Accordingly, redundant description is omitted.

### Modification Example 5

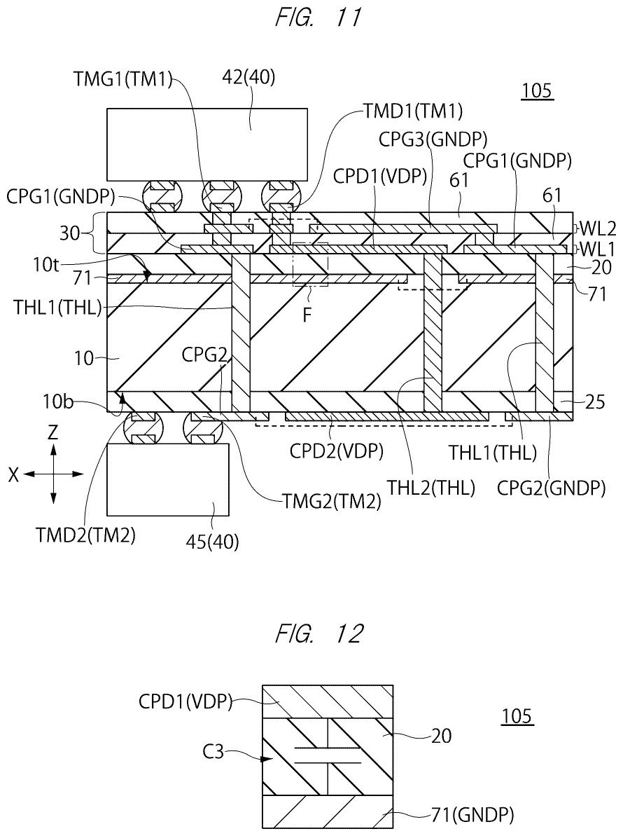

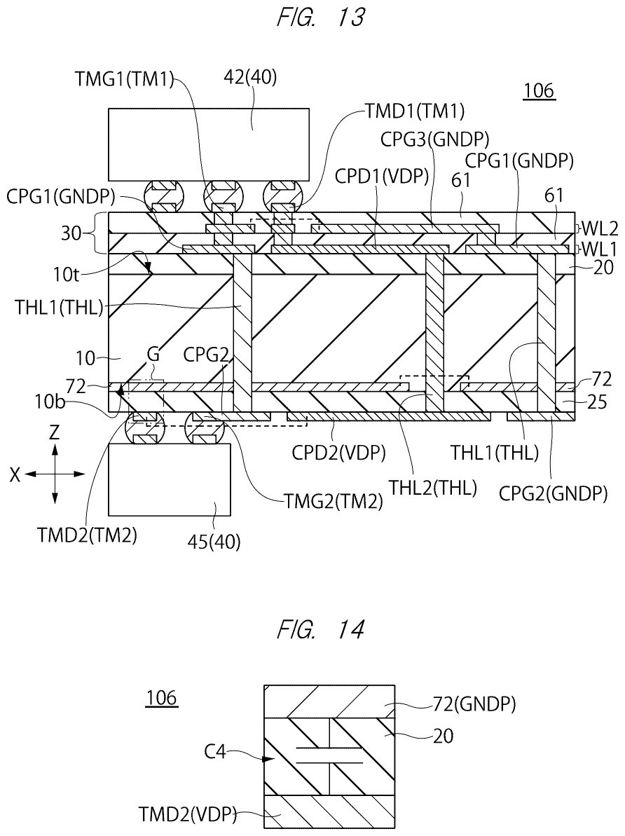

FIG. 11 is an enlarged cross-sectional view illustrating another modification example with respect to FIG. 2. FIG. 12 is an enlarged cross-sectional view illustrating a portion F of FIG. 11.

In the case of an electronic device 105 illustrated in FIGS. 11 and 12, a metal film 71 is disposed between the surface 10t of the glass substrate 10 (see FIG. 11) and the aluminum nitride film 20. The metal film 71 covers the surface 10t and is connected to the through-hole wiring THL1. Among the plurality of through-hole wirings THL, the through-hole wiring THL2 to which a power supply potential is supplied is spaced apart from the metal film 71. In other words, the power supply potential terminal TMD1 and the power supply potential pattern CPD1 electrically connected thereto are electrically separated from the metal film 71. However, as described later, the power supply potential pattern CPD1 and the metal film 71 are capacitively coupled.

The metal material constituting the metal film 71 is not particularly limited as long as it is a conductive material that can be bonded to the glass substrate 10 and the aluminum nitride film 20, and titanium (Ti) can be exemplified.

In the case of the electronic device 105, the metal film 71 is connected to the reference potential supply path GNDP. In addition, as illustrated in FIGS. 11 and 12, at least a part of the power supply potential pattern CPD1 faces the metal film 71 with the aluminum nitride film 20 interposed therebetween. Therefore, as illustrated in FIG. 12, a capacitor portion C3 in which the power supply potential pattern CPD1 and the metal film 71 are capacitively coupled is formed.

Since the capacitance of the capacitor portion C3 is proportional to the area of the region where the power supply potential pattern CPD1 and the metal film 71 face each other, the capacitance can be more easily increased as compared with the capacitor portion C1 illustrated in FIG. 3.

The plurality of through-hole wirings THL illustrated in FIG. 1 includes a through-hole wiring THLS serving as a signal transmission path that is connected to one of the plurality of electronic components 40. The metal film 71 illustrated in FIG. 11 is electrically separated from the through-hole wiring THLS serving as the signal transmission path.

FIG. 11 illustrates a modification example with respect to FIG. 2. Although not illustrated, the structure of the electronic device 105 according to the modification example may be combined with one or more of the structure of the electronic device 101 illustrated in FIGS. 4 and 5, the structure of the electronic device 102 illustrated in FIG. 6, the structure of the electronic device 103 illustrated in FIGS. 7 and 8, and the structure of the electronic device 104 illustrated in FIGS. 9 and 10.

The electronic device 105 illustrated in FIGS. 11 and 12 is the same as the electronic device 100 illustrated in FIGS. 2 and 3 except for the differences described above. Accordingly, redundant description is omitted.

### Modification Example 6

FIG. 13 is an enlarged cross-sectional view illustrating another modification example with respect to FIG. 2. FIG. 14 is an enlarged cross-sectional view illustrating a portion G of FIG. 13.

In the case of an electronic device 106 illustrated in FIGS. 13 and 14, a metal film 72 is disposed between the surface 10b of the glass substrate 10 (see FIG. 13) and the aluminum nitride film 25. The metal film 72 covers the surface 10b and is connected to the through-hole wiring THL1. Among the plurality of through-hole wirings THL, the through-hole wiring THL2 to which a power supply potential is supplied is spaced apart from the metal film 72. In other words, the power supply potential terminal TMD2 and the power supply potential pattern CPD2 electrically connected thereto are electrically separated from the metal film 72. However, the power supply potential pattern CPD2 and the metal film 72 are capacitively coupled.

The metal material constituting the metal film 72 is not particularly limited as long as it is a conductive material that can be bonded to the glass substrate 10 and the aluminum nitride film 25, and titanium (Ti) can be exemplified, similarly to the metal film 71 described with reference to FIG. 11.

In the case of the electronic device 106, the metal film 72 is connected to the reference potential supply path GNDP. In addition, as illustrated in FIG. 13, at least a part of the power supply potential pattern CPD2 faces the metal film 72 with the aluminum nitride film 20 interposed therebetween. Further, in the example illustrated in FIG. 14, the power supply potential terminal TMD2 that supplies a power supply potential to the electronic component 45 faces the metal film 72. Therefore, as illustrated in FIG. 14, a capacitor portion C4 in which the power supply potential terminal TMD2 and the metal film 72 are capacitively coupled is formed.

Since the capacitance of the capacitor portion C4 is proportional to the area of the region where the power supply potential terminal TMD2 and the metal film 72 face each other, the capacitance can be more easily increased as compared with the capacitor portion C2 illustrated in FIG. 8.

The metal film 72 illustrated in FIG. 13 is electrically separated from the through-hole wiring THLS illustrated in FIG. 1.

FIG. 13 illustrates a modification example with respect to FIG. 2. Although not illustrated, the structure of an electronic device 106 according to the modification example may be combined with one or more of the structure of the electronic device 101 illustrated in FIGS. 4 and 5, the structure of the electronic device 102 illustrated in FIG. 6, the structure of the electronic device 103 illustrated in FIGS. 7 and 8, the structure of the electronic device 104 illustrated in FIGS. 9 and 10, and the structure of the electronic device 105 illustrated in FIGS. 11 and 12.

The electronic device 106 illustrated in FIGS. 13 and 14 is the same as the electronic device 100 illustrated in FIGS. 2 and 3 except for the differences described above. Accordingly, redundant description is omitted.

### Modification Example 7

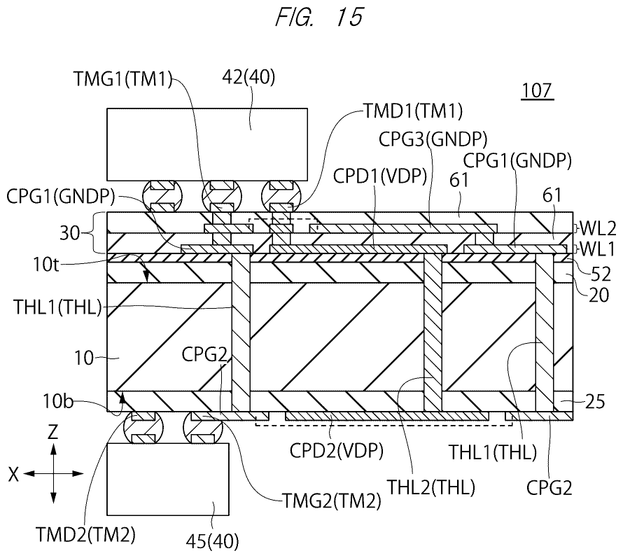

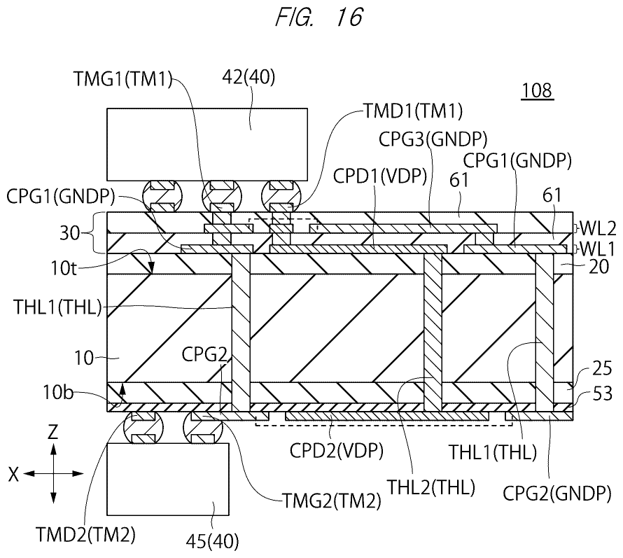

FIG. 15 is an enlarged cross-sectional view illustrating another modification example with respect to FIG. 2. FIG. 16 is an enlarged cross-sectional view illustrating another modification example with respect to FIG. 2.

As described with reference to FIG. 2, each of the plurality of conductor patterns constituting the wiring portion 30 is made of, for example, copper or a copper alloy. Specifically, each of the wiring layer WL1, the wiring layer WL2, and the plurality of terminals TM1 illustrated in FIG. 2 is made of copper or a copper alloy. Accordingly, since the resistance component of a signal transmission path passing through the wiring portion 30 can be reduced, wiring delay due to a CR product can be reduced.

In addition, each of the plurality of terminals TM2, the power supply potential pattern CPD2, and the reference potential pattern CPG2 formed on the surface 10b of the glass substrate 10 is made of copper or a copper alloy. Accordingly, the resistance component of a signal transmission path passing through any of the plurality of terminals TM2 can be reduced.

Meanwhile, considering adhesion to conductor patterns made of copper or a copper alloy, it is preferable that the underlying insulating layer of the wiring layer WL1 and the underlying insulating layer of the plurality of terminals TM2 be made of an insulating material having higher adhesion to copper or a copper alloy than aluminum nitride. The modification example is a modification example that can improve adhesion between the wiring material made of copper or a copper alloy and the underlying insulating layer.

In the case of an electronic device 107 illustrated in FIG. 15, an inorganic insulating layer 52, which is an inorganic oxide film containing silicon or a metal oxide film containing aluminum, is interposed between the wiring layer WL1 and the aluminum nitride film 20. The inorganic insulating layer 52 is in contact with the wiring layer WL1. In other words, in the case of the electronic device 107, the underlying insulating layer of the wiring layer WL1 is the inorganic insulating layer 52.

Examples of materials constituting the inorganic insulating layer 52 include silicon dioxide (SiO₂), silicon oxynitride (SiON), aluminum oxide (AlO), and aluminum oxynitride (AlON). These inorganic materials (specifically, oxygen-containing inorganic insulators) have higher adhesion to copper or a copper alloy than the aluminum nitride film 20. Therefore, by disposing the inorganic insulating layer 52 as the underlying insulating layer, adhesion between the wiring layer WL1 and the underlying insulating layer can be improved. As a result, peeling of the wiring layer WL1 can be suppressed, and reliability can be improved.

In the case of an electronic device 108 illustrated in FIG. 16, an inorganic insulating layer 53, which is an inorganic oxide film containing silicon or a metal oxide film containing aluminum, is interposed between the plurality of terminals TM2 and the aluminum nitride film 25. The inorganic insulating layer 53 is in contact with the plurality of terminals TM2. In other words, in the case of the electronic device 108, the underlying insulating layer of the plurality of terminals TM2 is the inorganic insulating layer 53.

As examples of materials constituting the inorganic insulating layer 53, silicon dioxide (SiO₂), silicon oxynitride (SiON), aluminum oxide (AlO), and aluminum oxynitride (AlON) can be exemplified, similarly to the inorganic insulating layer 52 illustrated in FIG. 15. These inorganic materials (specifically, oxygen-containing inorganic insulators) have higher adhesion to copper or a copper alloy than the aluminum nitride film 25. Therefore, by disposing the inorganic insulating layer 53 as the underlying insulating layer, adhesion between the plurality of terminals TM2 and the underlying insulating layer can be improved. As a result, peeling of the plurality of terminals TM2 can be suppressed, and reliability can be improved.

In FIGS. 15 and 16, examples have been described in which one of the inorganic insulating layer 52 and the inorganic insulating layer 53 is formed. However, as a modification example, both the inorganic insulating layer 52 and the inorganic insulating layer 53 may be formed.

In addition, each of FIGS. 15 and 16 is illustrated as a modification example with respect to FIG. 2. Although not illustrated, the structure of the electronic device 107 according to the modification example may be combined with one or more of the structure of the electronic device 102 illustrated in FIG. 6, the structure of the electronic device 103 illustrated in FIGS. 7 and 8, the structure of the electronic device 104 illustrated in FIGS. 9 and 10, the structure of the electronic device 105 illustrated in FIGS. 11 and 12, and the structure of the electronic device 106 illustrated in FIGS. 13 and 14. Also, the structure of the electronic device 108 according to the modification example may be combined with one or more of the structure of the electronic device 101 illustrated in FIGS. 4 and 5, the structure of the electronic device 102 illustrated in FIG. 6, the structure of the electronic device 103 illustrated in FIGS. 7 and 8, the structure of the electronic device 105 illustrated in FIGS. 11 and 12, and the structure of the electronic device 106 illustrated in FIGS. 13 and 14.

The electronic device 107 illustrated in FIG. 15 and the electronic device 108 illustrated in FIG. 16 are the same as the electronic device 100 illustrated in FIGS. 2 and 3 except for the differences described above. Accordingly, redundant description is omitted.

Although embodiments and representative modification examples have been described above, the above-described techniques can be applied to various modification examples other than the illustrated modification examples. For example, the modification examples described above may be combined with each other.

It is to be understood that various changes and modifications may be conceived by those skilled in the art within the scope of the spirit of the present invention, and such changes and modifications are also considered to fall within the scope of the present invention. For example, as to the above-described embodiments, additions, deletions, or design changes of components, or additions, omissions, or condition changes of steps, made as appropriate by those skilled in the art, also fall within the scope of the present invention as long as the gist of the present invention is retained.

The present invention is applicable to an electronic device.

What is claimed is:

1. An electronic device comprising:
a first glass substrate having a first surface and a second surface opposite to the first surface;
a first aluminum nitride film covering the first surface of the first glass substrate;
a second aluminum nitride film covering the second surface of the first glass substrate;
one or more wiring layers disposed on the first aluminum nitride film;
a plurality of first terminals disposed on the one or more wiring layers;
a first electronic component mounted on the plurality of first terminals;
a plurality of second terminals disposed on the second aluminum nitride film;
a second electronic component mounted on the plurality of second terminals; and
a first through-hole wiring embedded in a through-hole that penetrates the first aluminum nitride film, the second aluminum nitride film, and the first glass substrate,
wherein the plurality of first terminals includes,
a first reference potential terminal capable of supplying a reference potential to the first electronic component, and
a first power supply potential terminal capable of supplying a first power supply potential to the first electronic component,
wherein the plurality of second terminals includes a second reference potential terminal capable of supplying the reference potential to the second electronic component,
wherein a first power supply potential supply path connected to the first power supply potential terminal and a first reference potential supply path connected to the first reference potential terminal are disposed so as to be adjacent to each other in any of the one or more wiring layers, and
wherein each of the first reference potential terminal and the second reference potential terminal is electrically connected via the first through-hole wiring.

2. The electronic device according to claim 1,
wherein the one or more wiring layers include a first wiring layer disposed on the first aluminum nitride film, and
wherein the first wiring layer includes
a first reference potential pattern connected to the first through-hole wiring, and
a first power supply potential pattern electrically connected to the first power supply potential terminal, and
wherein, in the first wiring layer, a first side surface of the first reference potential pattern and a second side surface of the first power supply potential pattern face each other.

3. The electronic device according to claim 2,
wherein each of the first reference potential pattern and the first power supply potential pattern of the first wiring layer is covered with a first organic insulating film; and
wherein a relative dielectric constant of the first organic insulating film is lower than a relative dielectric constant of the first aluminum nitride film.

4. The electronic device according to claim 3,
wherein at least a part of each of the first reference potential pattern and the first power supply potential pattern is disposed in any of a plurality of first recesses provided in the first aluminum nitride film, and
wherein a portion of the first aluminum nitride film is interposed between the first side surface of the first reference potential pattern and the second side surface of the first power supply potential pattern.

5. The electronic device according to claim 3,
wherein a first inorganic insulating layer is interposed between a layer in which the plurality of first terminals is disposed and the first organic insulating film.

6. The electronic device according to claim 2,
wherein each of the plurality of first terminals, the first wiring layer, and the first through-hole wiring is made of copper or a copper alloy.

7. The electronic device according to claim 2,
wherein the plurality of second terminals is in contact with the second aluminum nitride film, and
wherein a thickness of the second aluminum nitride film is greater than a thickness of the first aluminum nitride film.

8. The electronic device according to claim 7,
wherein a plurality of second conductor patterns including the plurality of second terminals is disposed on the second aluminum nitride film,
wherein each of the plurality of second conductor patterns is in contact with the second aluminum nitride film,
wherein the plurality of second conductor patterns includes
a second power supply potential terminal included in the plurality of second terminals and configured to supply a second power supply potential to the second electronic component,
a second reference potential pattern connected to the first through-hole wiring, and
a second power supply potential pattern connected to the second power supply potential terminal, and
wherein in a layer in which the second terminals are formed, a third side surface of the second reference potential pattern and a fourth side surface of the second power supply potential pattern face each other.

9. The electronic device according to claim 8,
wherein at least a part of each of the second reference potential pattern and the second power supply potential pattern is disposed in any of a plurality of second recesses provided in the second aluminum nitride film, and
wherein a portion of the second aluminum nitride film is interposed between the third side surface of the second reference potential pattern and the fourth side surface of the second power supply potential pattern.

10. The electronic device according to claim 2,
wherein a first metal film is interposed between the first surface of the first glass substrate and the first aluminum nitride film, and
wherein the first metal film covers the first surface and is connected to the first through-hole wiring.

11. The electronic device according to claim 2,
wherein a second metal film is interposed between the second surface of the first glass substrate and the second aluminum nitride film, and
wherein the second metal film covers the second surface and is connected to the first through-hole wiring.

12. The electronic device according to claim 6,
wherein a second inorganic insulating layer, which is an inorganic oxide film containing silicon or a metal oxide film containing aluminum, is interposed between the first wiring layer and the first aluminum nitride film, and
wherein the second inorganic insulating layer is in contact with the first wiring layer.

13. The electronic device according to claim 2,
wherein each of the first wiring layer, the plurality of second terminals, and the first through-hole wiring is made of copper or a copper alloy,
wherein a third inorganic insulating layer, which is an inorganic oxide film containing silicon or a metal oxide film containing aluminum, is interposed between the plurality of second terminals and the second aluminum nitride film, and
wherein the third inorganic insulating layer is in contact with the plurality of second terminals.
